(19) United States
(12) Patent Application Publication
(10) Pub. No.: US 2026/0130239 A1
(43) Pub. Date: May 7, 2026

(54) PACKAGING FOR SEMICONDUCTOR DEVICES FOR HIGH PERFORMANCE COMPUTING APPLICATIONS AND METHODS FOR FORMING THE SAME

(71) Applicant: Taiwan Semiconductor Manufacturing Company Limited, Hsinchu (TW)

(72) Inventors: Hsin-Yu CHEN, Taipei City (TW); Meng-Wei CHOU, Zhubei City (TW); Yu-Ting CHEN, Hsinchu City (TW); Yu-Hsiang HU, Hsinchu City (TW); Chien-Hsun LEE, Hsinchu (TW)

(21) Appl. No.: 18/934,315

(22) Filed: Nov. 1, 2024

(51) Int. Cl. H01L 23/538; H01L 21/48; H01L 23/00; H01L 23/31; H01L 23/367; H01L 23/498; H01L 25/00; H01L 25/065; H10B 80/00

(52) U.S. Cl. CPC H10W 70/611; H10W 70/05; H10W 70/685; H10W 90/00; H10W 90/701; H10B 80/00; H10W 40/22; H10W 70/66; H10W 74/141; H10W 74/15; H10W 90/724; H10W 90/733; H10W 90/734

(57) ABSTRACT

A semiconductor device and methods of forming the same. In some embodiments, a method for forming a semiconductor device includes forming a redistribution layer that includes connecting vias and a surface mount pad via and the top surface width of each via is larger than a bottom surface width. The method includes connecting a component to the redistribution layer by a plurality of μ-bumps and filling a gap between the component and the redistribution layer with a mold and an underfill. The method includes etching back the redistribution layer to expose the surface mount pad via and attaching a surface mount pad to the surface mount pad via. The surface mount pad is connected to the bottom surface width of the surface mount pad via and the surface mount pad includes a protrude. The method includes connecting a device to a bottom surface of the surface mount pad.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

Packaging substrates are used as structures for attaching semiconductor dies to a printed circuit board. A semiconductor package may include one or more semiconductor devices (e.g., semiconductor dies, interposer modules, etc.) mounted on a substrate. For example, in wafer-scale heterogeneous integration devices, various different semiconductor materials, such as processing units, are used on a single carrier, such as a wafer, to enable advanced modern computing applications. Wafer-scale heterogeneous integration devices provide powerful systems with diverse functionalities, such as high performance computing and artificial intelligence.

While heterogeneous integrated devices provide high-speed applications, such as artificial intelligence, multiple challenges exist. For example, wafer-scale heterogeneous integration devices face challenges with yields and defects, material compatibility, thermal management, and bond alignment and strength.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an example schematic of a vertical cross-sectional view of forming an initial layer of the redistribution layer and a blown-up view of a surface mount pad via according to various embodiments of the present disclosure.

FIG. 1B is an example schematic of a vertical cross-sectional view of forming a secondary layer of the redistribution layer and a blown-up view of a surface mount pad via according to various embodiments of the present disclosure.

FIG. 1C is an example schematic of a vertical cross-sectional view of a redistribution layer and a blown-up view of a connecting via according to various embodiments of the present disclosure.

FIG. 2A is an example schematic of a vertical cross-sectional view of bonding the redistribution layer to a carrier according to various embodiments of the present disclosure.

FIG. 2B is an example schematic of a vertical cross-sectional view of connecting components to the redistribution layer using microbumps (μ-bumps) and a blown-up view of a μ-bump according to various embodiments of the present disclosure.

FIG. 2C is an example schematic of a vertical cross-sectional view of forming an underfill layer and a mold layer according to various embodiments of the present disclosure.

FIG. 2D is an example schematic of a vertical cross-sectional view of debonding and bonding various carriers according to various embodiments of the present disclosure.

FIG. 2E is an example schematic of a vertical cross-sectional view of forming surface mount pads with a blown-up view of a surface mount pad of a ball grid array (BGA) according to various embodiments of the present disclosure.

FIG. 2F is an example schematic of a vertical cross-sectional view of applying grind tape to the BGA to protect the BGA during subsequent grinding and cleaning processes according to various embodiments of the present disclosure.

FIG. 2G is an example schematic of a vertical cross-sectional view of a drilling and cleaning process according to various embodiments of the present disclosure.

FIG. 2H is an example schematic of a vertical cross-sectional view of connecting devices to the surface mount pads according to various embodiments of the present disclosure.

FIG. 2I is an example schematic of a vertical cross-sectional view of attaching a thermal module according to various embodiments of the present disclosure.

FIG. 3 is an example schematic of a top-view of a semiconductor device according to various embodiments of the present disclosure.

FIG. 4 is an example flowchart illustrating a method of forming a semiconductor device according to an embodiment of the present disclosure.

FIG. 5 is an example flowchart illustrating a method of forming a surface mount pad according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Ordinals such as “first,” “second,” “third,” etc. are not an inherent part of a name of any element, and are used only for the purpose of individually identifying multiple elements having the same, or similar, characteristics, and thus, different ordinals may be used for a same element across the specification and the claims. For example, a second element in the specification may be referred to as a first element in the claims.

Elements with the same reference numerals refer to the same element, and are presumed to have the same material composition and the same thickness range unless expressly indicated otherwise. As used herein, an element or a system “configured for” a function or an operation or “configured to” provide or perform a function or an operation.

Wafer-scale system integration technologies, such as an integrated fan out system on wafer (InFO-SoW) device, combine multiple semiconductor materials onto a single wafer to enable advanced device applications. For example, wafer-scale system integration technologies may incorporate compute elements, memory, input/output components, passive chiplets, and other components through functional integration. InFO devices particularly provide high bandwidth density, low latency chip-to-chip communication, and low power delivery network impedance. Wafer-scale system integrated devices have applications in high performance computing (HPC), integration of electrochemical devices, self-powered chips, implantable health monitoring systems, fully integrated chemical analytic chips, and artificial intelligence.

A method for forming a wafer-scaled integrated device begins with a pick and place process placing components on a carrier followed by a molding and grinding process. The components may be inverted with their connection mounting pads or micro bumps facing upwards. Next, in such methods, a redistribution layer (RDL) is formed above the components layer by layer. In other words, a layer of dielectric material is placed above the components and then a via is formed within the dielectric material layer. To form the vias, typically, a cavity may be formed by etching and then subsequently filled with a conductive material. As a result of the orientation of the components during the formation of the RDL, the formed vias are typical formed with a trapezoidal shape where the dimension of the top of the via (side facing away and distal from the mounting pads or micro-bumps) is larger than that of the bottom of the via (i.e., side proximal to the mounting pads or micro-bumps). In such methods, the bottom of the via having smaller width is connected to the components. Another layer of dielectric material may be placed above the via layer and a metal trace may be formed within the another layer of dielectric material placed over the via layer. This formation process of the RDL continues to build up layers of dielectric material with either vias or metal traces in each layer. Once the RDL is fully formed, a ball grid array (BGA) mount pad may be formed above the RDL. Again, due to the orientation of the components and RDL during the formation process, the via connected to the BGA mount pad includes a trapezoidal shaped with the wider width surface, or the top of the via, connected to the BGA mount pad. Additionally, the BGA mount pad is formed above the redistribution layer which causes the surface mount pad to have a concave shape above the top layer via of the RDL.

While wafer-scale system integration technologies improve device performance and power efficiency, wafer-scale system integration technologies remain complex with multiple challenges. For example, wafer-scale heterogeneous integration devices commonly have issues with yield and defects. In more detail, wafer-scale heterogeneous integration devices require the integration of multiple dies on a single wafer. Due to the size and complexity of the integrated systems, high yield is challenging or, in some instances, impossible. Yield loss may be due to defects in transistor layers or high-density lower metal layers. Additionally, by forming the RDL above the components, described above, defects in the RDL, such as misalignment or improper connections, may cause the entire semiconductor device to be defective. Malformations or defects that occur during the formation of the RDL impact the yield of not only the RDL, but also the yield of the components placed under the RDL during the formation process.

Additionally, wafer-scale heterogeneous integration devices face challenges with thermal management. Due to the high computational density, the wafer-scale heterogeneous integration devices generate large amounts of heat. More specifically, improper thermal management and/or yield loss may cause defective devices causing the issues in efficiency, performance, and in some cases, complete loss of use. By forming and configuring the vias of the RDL such that the smaller width side of the via is proximal to the heat generating components, thermal conductivity of the heat generated by the components may be limited. Therefore, effective thermal management strategies may mitigate against overheating and ensure reliable operation of the device.

Various embodiments disclosed herein are directed to semiconductor devices, such as a wafer-scale heterogeneous integration devices or an organic interposer chip on wafer (CoW-R) system on wafer (SoW) structures. Various embodiments may improve thermal management of the semiconductor device and improve yield loss. By forming the RDL and then subsequently attaching components to the RDL, the RDL may be tested for defect before the components are attached. In addition, by forming the RDL separate from the components, the components may be spared from damage that may occur due to the formation of the RDL. Both of these advantages may improve overall semiconductor device yield. Additionally, by forming and configuring the RDL such that a wider side of the vias of the RDL are proximal to the heat generating components, improved thermal management may be achieved. Further, the formation of the BGAs as described below may improve the bond alignment and strength of the connections between the semiconductor device and connectors and or devices. The semiconductor device may provide high bandwidth memory (HBM) components for high performance computing (HPC) applications and a methods for forming the same.

In an embodiment, the semiconductor device may include a connector, a voltage regulator module (VRM), a redistribution layer, high bandwidth memory (HBM), a system on a chip (SoC), an input/output (IO) component, a μ-bump structure, underfill and mold materials, a ball-grid array (BGA), and a thermal module. The redistribution layer may distribute contact points between devices and result in thermal dissipation resulting in enhanced thermal management. The orientation and shape of the surface mount pads may promote the flow of heat vertically resulting in reduced thermal resistance and enhanced heat dissipation.

An alternative embodiment is directed to a method of forming the semiconductor device, such as the organic chip on wafer interposer (CoW-R) system on wafer (SoW) structure. In some embodiments, the method forms a redistribution layer that includes a trapezoidal via with an angle θ between a bottom portion and a side portion of the via greater than 90° that enhances thermal performance by allowing better heat dissipation between components and therefore reducing overall thermal resistance. In some embodiments, the redistribution layer further includes a seed layer that separates the via from the dielectric material. In some embodiments, the method forms components such as a high bandwidth memory component, system on a chip, or input/output component connected to the redistribution layer by μ-bumps. Embodiment methods may further fill a space between the components and the redistribution layer with a mold and an underfill. The underfill may dissipate heat produced by devices due to having a large surface area. The mold may further encapsulate the components and protect the components from damage, such as from heat. In some embodiment methods, a surface mount pad connected to the redistribution layer may be etched. The surface mount pad may include a via, a pillar, a seed layer, and a protruded pad. In some embodiment methods, a device such as a connector or a VRM may be connected to the surface mount pad through a BGA. The surface mount pads may enhance heat dissipation by promoting the flow of heat vertically between devices and the RDL and therefore reducing thermal resistance. Additionally, the surface mount pads may minimize the thermal path due to the large surface area to allow for heat dissipation.

Various embodiments disclosed herein may provide various advantages and improvements. For example, embodiments of the disclosed invention provide for proper integration between the RDL, chip array, HBM, power module, and thermal module within a semiconductor device. More specifically, embodiments ensure HBM components are connected to an RDL without defects therefore improving yield. Additionally, the RDL improves heat dissipation between the power module and HBM module therefore improving thermal management with the aid of the thermal module. As a result, the disclosed embodiments may improve HPC applications while regulating heat produced by the semiconductor device. Some embodiments may utilize a die last approach which may increase yield and mitigate against HBM and SoC yield loss. Additionally, some embodiments may utilize an organic interposer and HBM die last approach. The organic interposer and die last approach may mitigate against HBM thermal concerns by dissipating heat more effectively through the die that is bonded to the HBM. Some embodiments may provide thermal regulated and power efficient semiconductor devices capable of performing HPC applications. For example, the RDL may distribute heat produced by devices and provide thermal dissipation while the surface mount pads may allow heat to flow vertically between the devices and RDL reducing in thermal resistance and improving heat dissipation. Various embodiments provide advantages and improvements in thermal management and yield loss in semiconductor devices that incorporate HBM components.

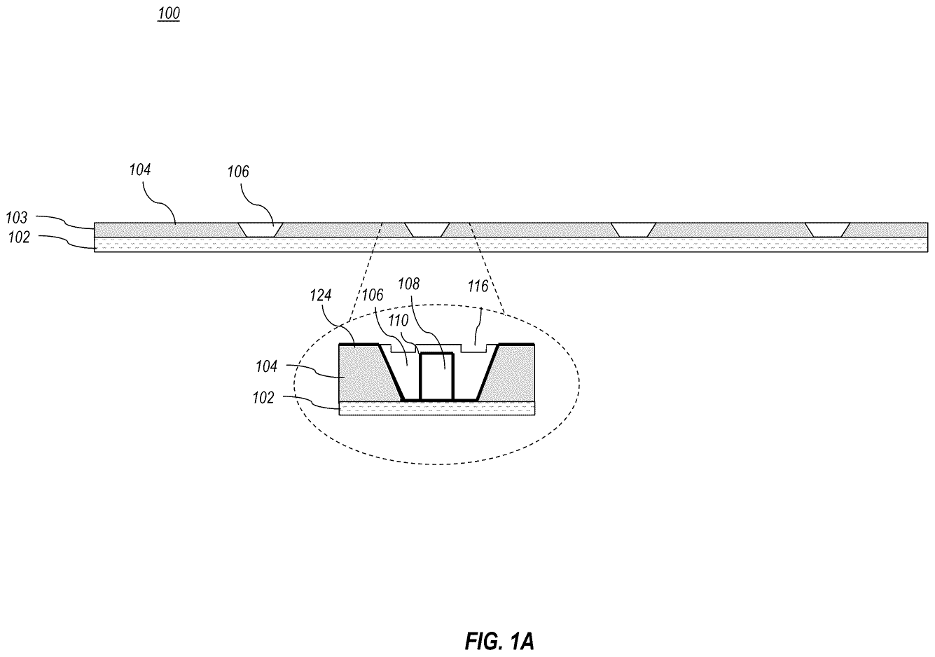

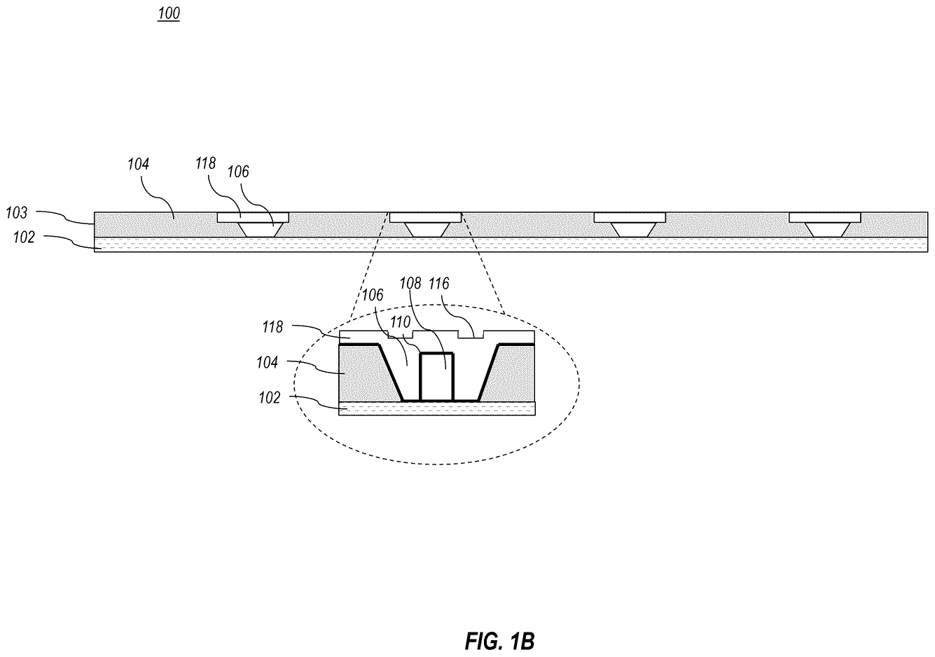

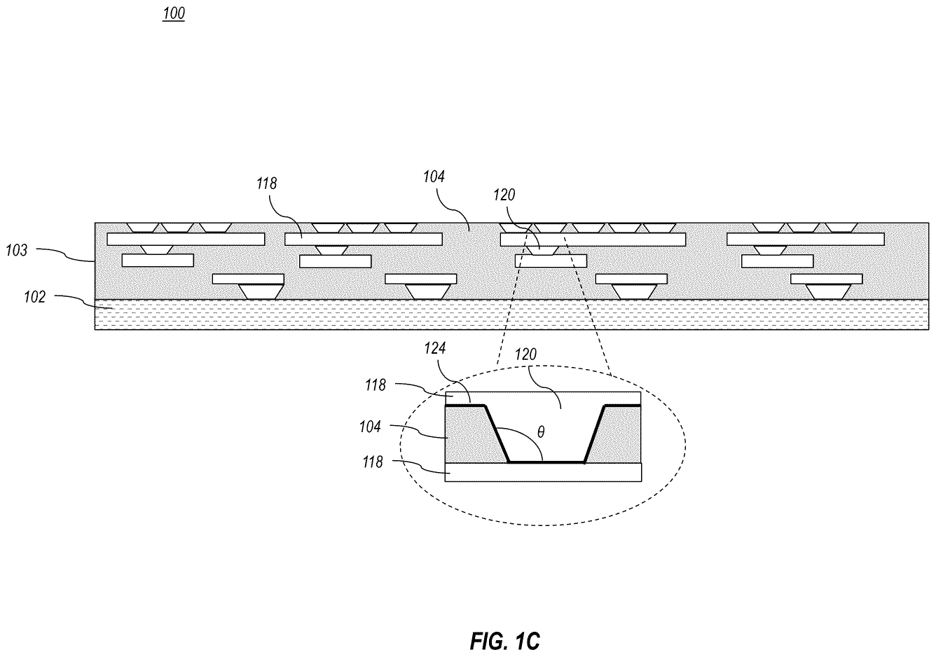

Referring now to the figures, FIGS. 1A-1C illustrate various steps in forming a redistribution layer (RDL) 103 for a semiconductor structure 100. In some embodiments, the RDL 103 may increase package density by allowing a high pin count and increasing functionality within small device packaging. The RDL 103 may also provide improved electrical performance due to short interconnect lengths that contribute to reduced power consumption and increase signal speeds. The RDL 103 may be used to integrate multiple types of chips and components within a single semiconductor device by providing multiple electrical connections. Additionally, the RDL 103 may distribute the contact points among various devices connected to the RDL 103. This distribution of contact points results in thermal dissipation that enhances thermal management within the semiconductor structure 100. The enhanced thermal management further results in optimized heat transfer throughout the semiconductor device and reduces overheating and therefore may improve reliability.

FIG. 1A illustrates an example of forming a first layer of the RDL 103. The RDL 103 includes a dielectric material layer 104 on top of a carrier substrate 102. The dielectric material layer 104 may be formed of a polymeric material and the carrier substrate 102 may be formed of an oxide. Various electric and oxide materials are within the contemplated scope of disclosure.

Also shown in FIG. 1A is a blown-up view of a surface mount pad via 106. In some embodiments, surface mount pad vias 106 may be formed in the dielectric material layer. The vias 106 may be formed by through a variety of processes. For example, a cavity may be formed by etching or patterning a first dielectric material layer of the RDL. Once the cavity is created, a subsequent polishing step, such as a chemical mechanical polishing, may be performed to smooth the sides of the cavity. In order to provide a via of sufficient size to support a subsequently formed BGA, the cavity may be dimensioned with a corresponding width. In some embodiments, the via 106 has a trapezoidal shape where a width of a top portion of the via 106 is larger than a width of a bottom portion of the via 106.

In an embodiment, a pillar 108 may be formed in the cavity. A seed layer 124 may be conformally deposited in the cavity. The seed layer 124 may be deposited by a chemical vapor deposition (CVD), atomic vapor deposition (AVD), or other appropriate deposition methods. In some embodiments, the seed layer 124 is formed of titanium, titanium tungsten, titanium nitride, or other appropriate material. Other seed layer materials are within the contemplated scope of disclosure. The seed layer 124 may promote the growth of a conductive material such as copper or other conductive material. Due to the dimensions and width of the cavity, conductive material may be difficult to grow in the cavity. The pillar 108 may be formed in the central portion of the cavity. The pillar 108 may be etched to leave the pillar core of conductive material in the cavity. The pillar 108 may be formed of a conductive material such as copper, silver, gold, tungsten, or other appropriate conductive material. The pillar 108 may be grown through an electroplating process or other process. Subsequent to shaping and etching the pillar core, an additional seed layer 110 may be deposited around and over the pillar 108 and on the surface of the remainder of the cavity. The seed layer 110 may be deposited by a chemical vapor deposition (CVD), atomic vapor deposition (AVD), or other appropriate deposition methods. In some embodiments, the seed layer 110 may be the same material as seed layer 124 or may be a different seed layer material. The seed layer 110 may act as a foundation for additional metal deposition and ensure strong adhesion between layers while promoting uniform nucleation of metal firms resulting in improved coverage and reliability. The additional metal deposition may assist in the filling of the cavity and provide a via with improved strength characteristics that mitigate against damage subsequently when the semiconductor structure 100 is compressively placed to attach connectors and VRMs. Additionally, the seed layer 110 may serve as a conductive path to improve flow between the RDL layers. The seed layer 110 may act as a barrier that prevents diffusion between the metal traces 118 and vias 106 and the dielectric layer 104.

In an embodiment, the conductive material is grown in the cavity to form the via 106. In some embodiments, the pillar 108 reduces the amount of conductive material required to fill the cavity. Because the dielectric material 104 is formed of an organic material, such a polymeric material, the difference between the thermal expansion coefficients of the dielectric material 104 and the conductive material in the via 106 is large. Therefore, reducing the amount of conductive material to fill the cavity by forming a pillar 108 first surrounded by a seed layer 110 then subsequently filling the cavity to form the via 106 improves thermal mitigation due to the thermal coefficients. Due to the pillar 108 being formed first, a divot 116 may be formed above the portions surrounding the pillar 108 because the conductive material is formed conformally.

FIG. 1B illustrates an example of forming a second metal trace layer in the RDL 103 and a blown-up view of the surface mount pad via 106 and metal trace 118. In an embodiment, an additional layer of dielectric material is added to the dielectric material layer 104. The dielectric material layer 104 may be etched to pattern cavities in which metal traces 118 may be formed. The conductive material may be conformally deposited within the patterned cavities in the additional dielectric layer to form metal traces 118. The metal traces 118 may be located above the vias 106. In some embodiments, the metal traces 118 are formed out of a conductive material, such as copper, silver, gold, tungsten, or other appropriate materials. The metal traces 118 may be formed conformally above the vias 106 and therefore include divots 116. A polishing process, such as a chemical mechanical polish (CMP) process or grinding process may be used to form a singular top surface plane and remove the presence of the divots 116 in the first metal trace layer of the RDL.

FIG. 1C illustrates an example of forming additional dielectric layers 104 and via layers and metal trace layers 118 of the RDL 103. FIG. 1C also illustrates a magnified view of a connecting via 120. In an embodiment, the RDL 103 includes six layers (alternating layers of vias 106, 120 and metal traces 118 formed in dielectric layers 104). In alternative embodiments, the RDL 103 includes four layers, five layers, six layers, seven layers, ten layers, or more than ten layers. Each layer may include dielectric material 104 and either a via (e.g., surface mount pad via 106 or connecting via 120) or a metal trace 118.

In some embodiments, the connecting vias 120 may be formed by a variety of processes. For example, a cavity may be formed by etching or patterning in the respective dielectric material layer 104. The patterning may occur for a specified amount of time or until a metal trace 118 is identified. Once the cavity is created, a subsequent polishing step, such as a chemical mechanical polishing, may be performed to smooth the sides of the cavity.

Subsequent to forming the cavity, a seed layer 124 may be deposited on the surface of the cavity by either CVD, AVD, or other appropriate deposition methods. In some embodiments, the seed layer 124 is formed of titanium, titanium tungsten, titanium nitride, or other appropriate material. The cavity may be filled with a conductive material, such as copper, tungsten, silver, gold, or other appropriate material to form the connecting via 120 (or metal trace 118). Other seed layer materials are within the contemplated scope of disclosure. The seed layer 124 may act as a foundation for metal deposition and ensure strong adhesion between layers while promoting uniform nucleation of metal firms resulting in improved coverage and reliability. Additionally, the seed layer 124 may serve as a conductive path to improve flow between the various RDL layers. The seed layer 124 may act as a barrier that prevents diffusion between the metal traces 118 and vias 120 and the dielectric layer 104.

Subsequent to the seed layer 124 being deposited, the cavity is filled with a conductive material or a conductive material is grown in the cavity. Similar to the surface mount pad via 106, the connecting via 120 may be formed with a trapezoidal shape where a top surface width is larger than a bottom surface width. In other words, an angle θ between a side portion of the via 120 and a bottom surface width of the via 120 is greater than 90°.

In the instance in which the via 120 is formed in an intermediate layer of the RDL 103, a metal trace 118 may be formed on top of the via 120. In the instance in which the via 120 is the last layer in the RDL 103, no metal trace 118 is added above the via 120. In some embodiments, the surface mount pad via 106 is larger than the connecting vias 120. Due to this, the connecting vias 120 do not include a pillar and instead are filled with conductive material in a single step.

In an embodiment, the RDL 103 may be tested after its formation to ensure a reliable RDL 103 prior to being used in the final semiconductor structure 100. By testing the RDL 103 at this point, embodiments of the invention and stable RDL 103 and therefore improve overall yield.

In some embodiments, the network of fine metal traces 118 and vias (e.g., surface mount pad vias 106 and connecting vias 120) within the RDL 103 optimizes the signal path by providing contact when components and devices are attached or connected to the RDL 103. Additionally, the RDL 103 reduces overall size of the semiconductor structure 100 by allowing multiple components and devices to be connected to a single RDL 103 and be incorporated in a single semiconductor structure 100. Still further, the subsequent pick and placement of components on the top surface of the RDL 103 allow the components to be placed and connected to the wider top surface of the vias 120. This connection to the top surface of the vias 120 may promote the flow of heat from the heat generating components vertically away from the components through the RDL 103.

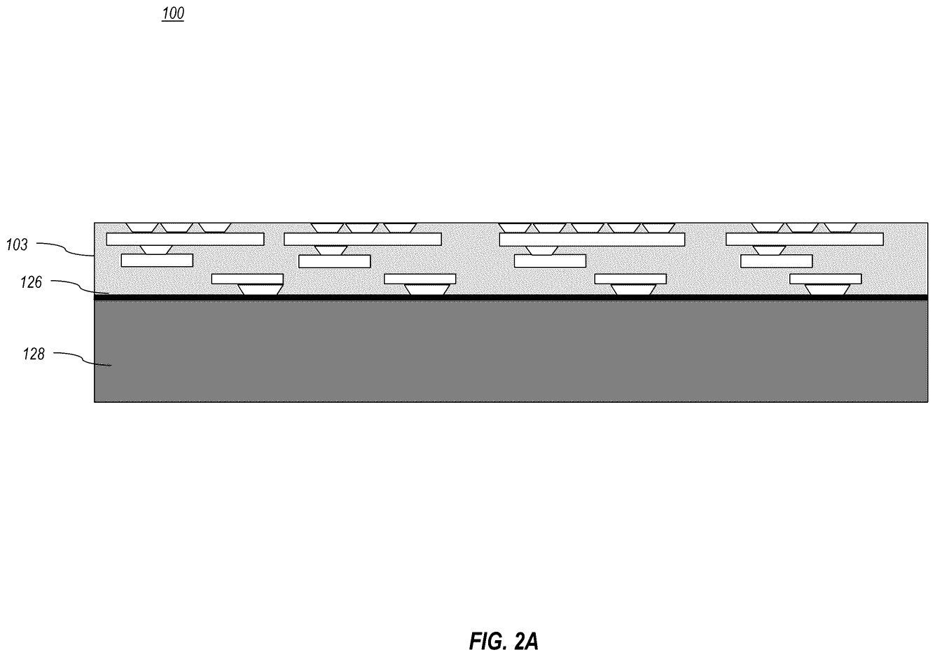

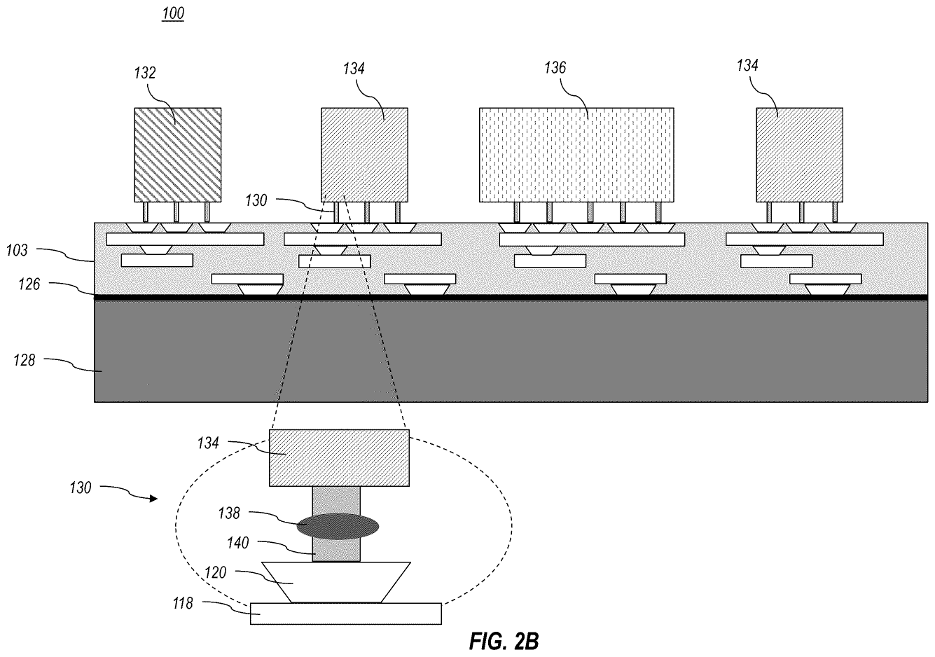

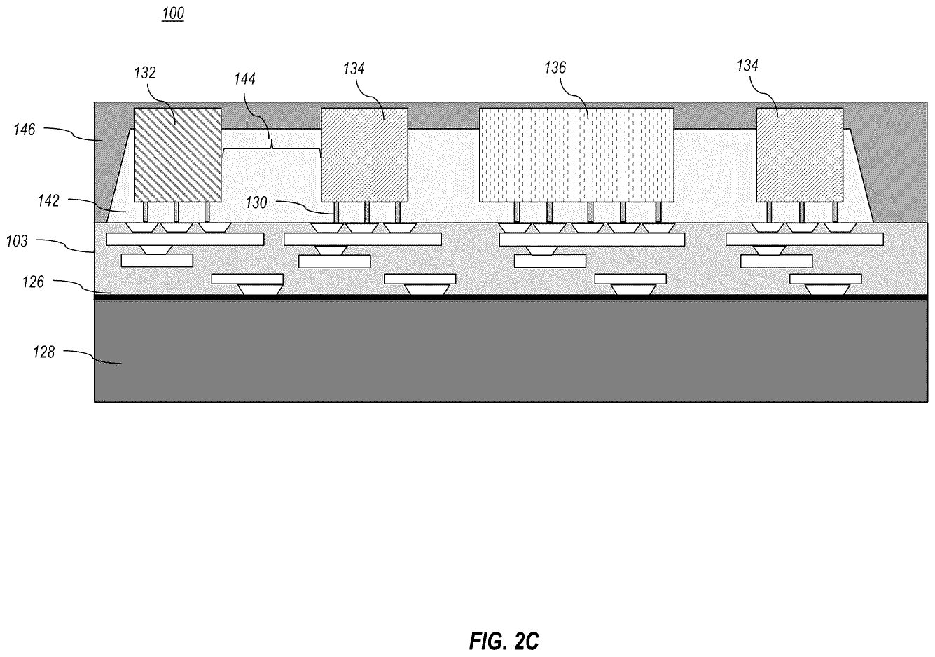

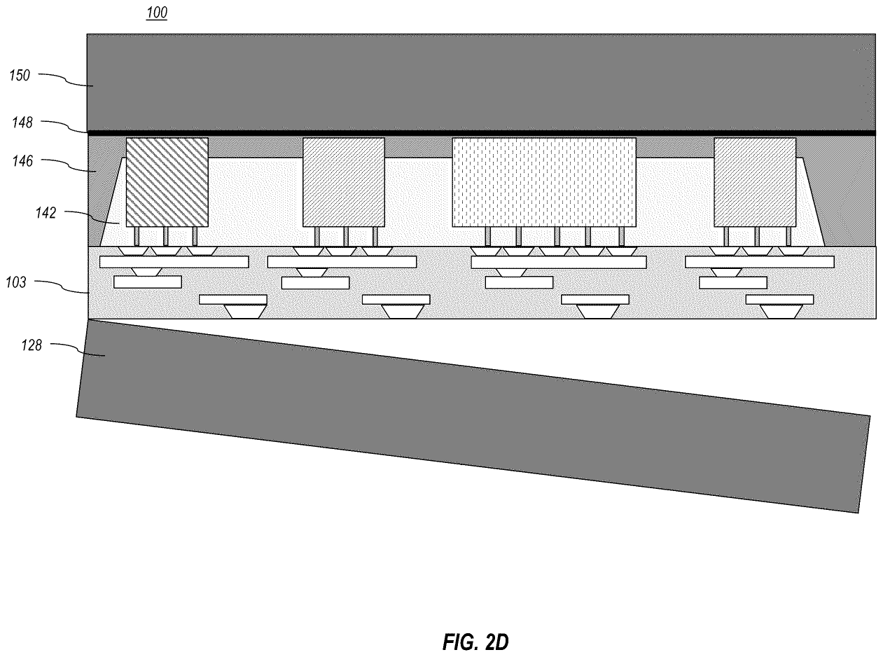

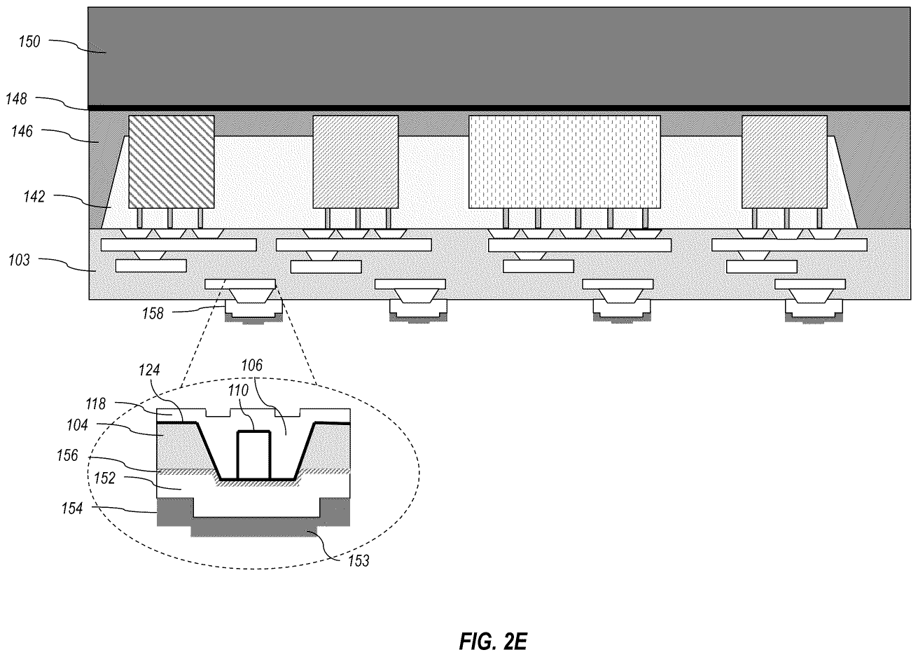

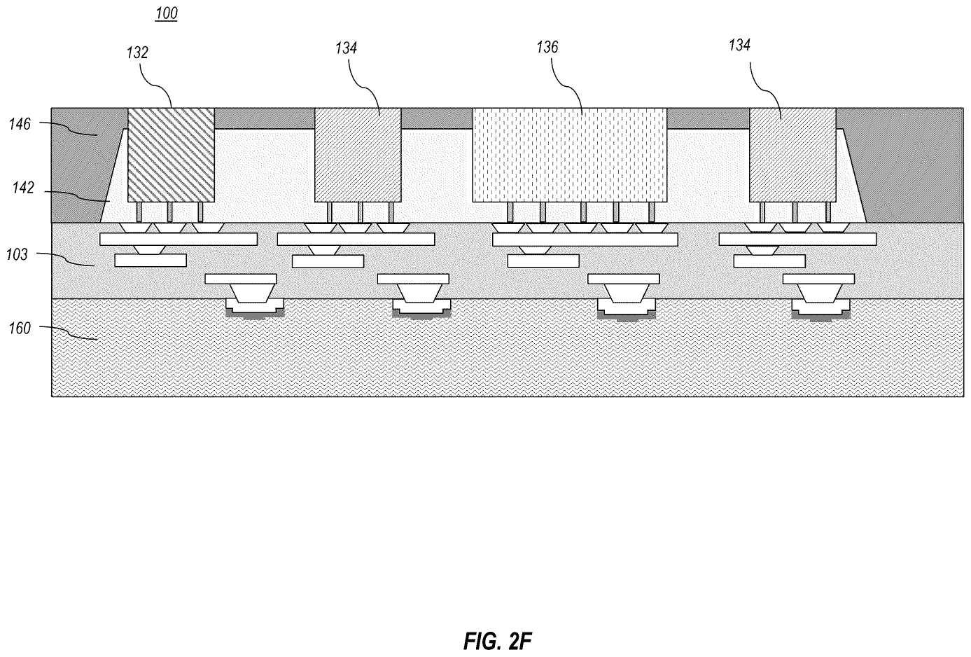

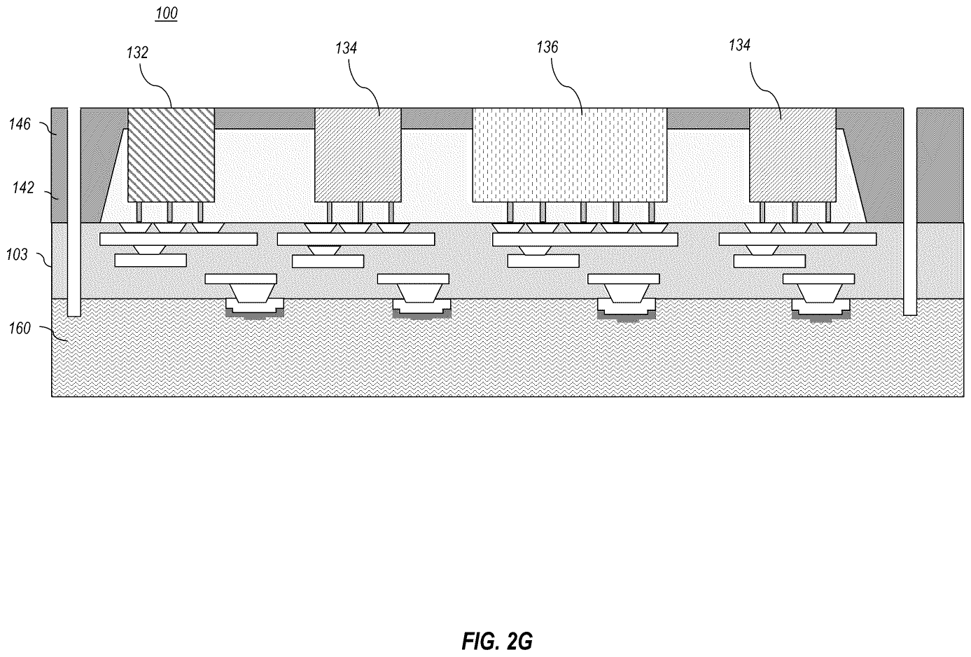

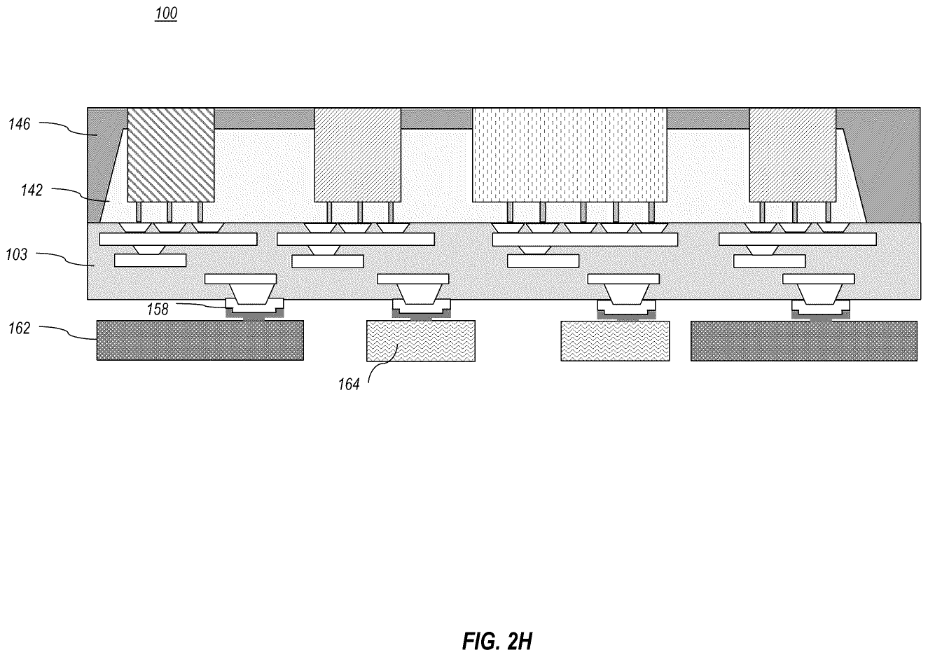

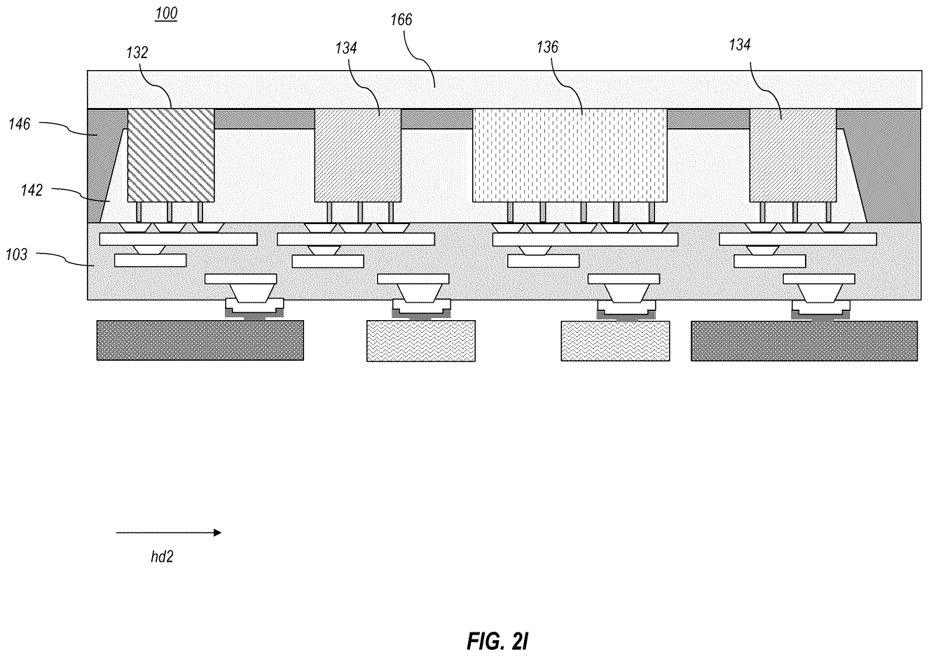

FIGS. 2A-2H illustrate an example of forming a semiconductor structure 100 after formation of the RDL 103. In some embodiments, the semiconductor structure 100 is a chip on wafer (CoW) for system on chip (SoW) structure. In an embodiment, the CoW structure includes an organic interposer (CoW-R).

FIG. 2A illustrates an example of an intermediate semiconductor structure having a redistribution layer (RDL) 103 temporarily bonded on a carrier wafer 128, for example, by an adhesive 126. The first carrier wafer 128 may comprise a circular wafer or a polygonal wafer such as a rectangular wafer. In instances in which the first carrier wafer 128 is a circular wafer, the diameter of the first carrier wafer 128 may be, for example, 100 mm, 300 mm, 450 mm, etc. Generally, the first carrier wafer 128 may comprise a semiconductor wafer, an insulating wafer, a conductive wafer, or a composite wafer having sufficient mechanical strength to support additional wafers to be subsequently attached thereto. The thickness of the first carrier wafer 128 may be in a range from 500 microns to 2 mm, although lesser and greater thicknesses may also be used. In one embodiment, the first carrier wafer 128 may comprise a commercially available silicon wafer.

A first adhesive layer 126 may be applied to the surface of the carrier wafer 128. In one embodiment, the first adhesive layer may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 126 may include a thermally decomposing adhesive material. For example, the first adhesive layer 126 may include an acrylic pressure-sensitive adhesive that decomposes at an elevated temperature. The debonding temperature of the thermally decomposing adhesive material may be in a range from 150 degrees to 100 degrees Celsius.

FIG. 2B illustrates an example of a further intermediate semiconductor structure 100 including a magnified view of the micro-bumps (μ-bumps) 130 that may be used to connect components (e.g., I/O component 132, HBM components 134, and SoC component 136) to the RDL 103. As shown in FIG. 1B, various components may be placed (e.g., using a pick-and-place (PNP) device) and may be connected to the RDL 103 via μ-bumps 130. In some embodiments, the components include a system on a chip (SoC) component 136, multiple high bandwidth memory (HBM) components 134, and multiple input/output (I/O) components 132. While only one SoC component 136 is illustrated in the cross-section, in some embodiments, more than one SoC component 136 may be present. Similarly, in some embodiments, one, two, three, or more than three HBM components 134 and/or I/O components 132 may be present. While SoC components 136, HBM components 134, and I/O components 132 are illustrated and described one skilled in the art will appreciate that other types of components may be present in various quantities and in various configurations.

In some embodiments, the μ-bumps 130 may be formed using a masking, deposition, electroplating, and reflow processes. Initially, a photoresist mask may be applied to define the areas where the μ-bumps 130 will be formed. A metal seed layer may initially be deposited. In some embodiments, the seed layer may be formed of titanium or copper. In some embodiments, the electroplating process includes electroplating a conductive material, such as copper, onto predefined seed layers, commonly formed of titanium or titanium-tungsten. Other conductive materials and seed layer materials are within the contemplated scope of disclosure. The photoresist layer may be stripped away leaving behind the μ-bumps 130. Finally, the μ-bumps 130 may undergo a reflow process to form the shape of the μ-bumps 130.

In some embodiments, the μ-bumps 130 may be formed of copper, tungsten, gold, silver, platinum, or other conductive material. The μ-bumps 130 may have a pitch that refers to the spacing between adjacent bumps 130. In some embodiments, the pitch of the μ-bumps 130 under each component may be between about 30 μm and about 160 μm, between about 40 μm and about 150 μm, or between about 80 μm and 120μm. The pitch of the μ-bumps 130 may determine the size and density of the connections of the corresponding components (e.g., SoC components 136, HBM components 134, and I/O components 132) that may be subsequently connected to the semiconductor structure 100 through the μ-bumps 130. In some embodiments, the μ-bumps 130 may have a size between about 20μm and 90μm, between about 25μm and about 80μm, or between about 30μm and about 50μm. The μ-bumps 130 may have a substantially consistent spacing between adjacent μ-bumps 130. In alternative embodiments, the μ-bumps 130 may have a substantially inconsistent spacing between adjacent μ-bumps 130.

The placement of the μ-bumps 130 may enhance heat dissipation and overcome electromigration challenges. For example, the μ-bumps 130 may provide an intermediary layer between the components e.g., SoC components 136, HBM components 134, and I/O components 132) and the RDL 103 to provide a pathway for the heat generated by the components to travel from the components to the RDL 103. Further, the μ-bumps 130 may enhance the thermal performance by acting as a solid-state heat pump. Additionally, the μ-bumps 130 provides mechanical support between the RDL 103 and components. Overall, the μ-bumps design provides improved heat dissipation and improved reliability and performance for the semiconductor structure 100.

The μ-bumps 130 electrically connect the components (e.g., SoC component 136, HBM component 134, and I/O component 132) with the RDL 103. In some embodiments, each component may be connected by a plurality of μ-bumps. Each μ-bump 130 is associated with a connecting via 120. Different components may be connected via different shapes, sizes, or number of μ-bumps 130. In other embodiments, the shape, size, and number of μ-bumps 130 may be consistent per component. In some embodiments, the μ-bumps 130 may enable high-density and low-latency communication between architectures, structures, or components.

Turning to the components, the SoC component 136 is an integrated circuit that combines multiple components onto a single chip. In some embodiments, the SoC component 136 may include one or more of: a central processing unit (CPU), microcontroller, memory interfaces, I/O interfaces, secondary storage devices, a graphics processing unit (GPU), radio modems, coprocessors, and/or other appropriate components. In some embodiments, the SoC component 136 may include analog, mixed-signal, and radio frequency signal processing features. In some embodiments, the SoC component 136 may be a microcontroller-based SoC with various peripherals, a microprocessor-based SoC that includes a microprocessor, a specialized application-specific SoC designed for specific applications, or other appropriate SoC device. In some embodiments, the incorporation of multiple components (e.g., CPU, GPU, coprocessors) in the SoC component 136 reduces power consumption. Additionally, incorporating multiple components in the single SoC component 136 reduces the die area of the semiconductor device and provides tighter integration of components.

In some embodiments, the SoC component 136 may reduce power consumption due to integrating multiple features into a single component therefore leading to higher power dissipation. Because the SoC component 136 incorporates multiple components, the functionality and performance of the SoC component 136 may be customized. The SoC component 136 also reduces the die area by incorporating multiple dies into a single component and therefore and providing improved integration of components. Additionally, the SoC component 136 may lower latency due to placing critical components in close proximity therefore increasing performance. The SoC component 136 may be located between two other components, such as two HBM components 134.

The HBM component 134 is a specialized computer-memory interface. In some embodiments, the HBM component 134 may be utilized as a 3D-stacked synchronous dynamic random-access memory (DRAM). The HBM component 134 achieves high bandwidth by stacking multiple DRAM dies vertically. In some embodiments, the HBM component 134 may stack multiple channels to provide wide memory bus. In some embodiments, the HBM component 134 utilizes thru-silicon vias (TSVs) to vertically interconnect the different memory dies. Other suitable conductive materials are within the contemplated scope of disclosure. Additionally, in some embodiments, microbumps, such as copper microbumps, may be formed on top of the die to create proper electrical connections with other components. The HBM component 134 is a memory architecture designed for HPC applications by providing higher bandwidth as compared to related memory technologies. In some embodiments, the HBM component 134 contains a stacked design with multiple memory dies stacked vertically creating a 3D structure. In some embodiments, the HBM component 134 may have a thickness of about 300 μm, about 400 μm, about 500 μm, about 700 μm, about 800 μm, or about 900 μm.

In some embodiments, the semiconductor structure 100 includes multiple HBM components 134 resulting in increased heat generation. While multiple HBM components 134 may provide higher memory bandwidth, it also concentrates the heat in a smaller space and increases the chance of overheating. The RDL 103 may improve the heat dissipation of the heat generated from the HBM components 134 and may improve overall thermal management. Due to the multiple memory dies within HBM component 134, in some embodiments the HBM component 134 may achieve high bandwidth by allowing simultaneous data access process across the multiple memory dies. The HBM 134 may also use a wide data bus to allow the HBM component 134 to transfer data between different components (e.g., a GPU or CPU and memory) and therefore enabling high bandwidth.

The I/O component 132 provides circuitry that allows for the exchange of data and signals between external devices and external devices (e.g., a monitor, speakers, a microcontroller). In some embodiments, the I/O component 132 may include input ports for receiving data and signals and output ports used for sending data and signals. The I/O component 132 may be a general-purpose I/O (GPIO) component that includes GPIO pins. In some embodiments, a user may dynamically change the function of the I/O component 132 during runtime of the I/O component 132. In some embodiments, the I/O component 132 has a thickness of about 300 μm, about 400 μm, about 500 μm, about 700 μm, about 800 μm, or about 900 μm. In some embodiments, the I/O component 132 may be located on an outer edge forming a sidewall 113 of the semiconductor structure 100 adjacent to an HBM component 134.

In some embodiments, the components (e.g., HBM component 134, SoC component 136, and I/O component 132) are attached to the RDL 103 using a die last approach. In the die last approach, the RDL 103 is formed on a carrier wafer (e.g., forming the RDL 103 on the carrier wafer 128) and a logic die is placed on the RDL 103. The logic die may be a CPU or a GPU. Subsequently, the component (e.g., SoC component 136, HBM component 134, and I/O component 132) and then the components are bonded on top of the logic die. The die last approach may improve thermal management by dissipating heat produced by the components through the logic die and further through the RDL 103. Further, by forming the HBM component 134 using a die last approach, the RDL 103 may be tested prior to forming the components. As a result, yield is improved because components, such as the HBM component 134, are not added to defective RDLs 103 therefore preventing an overall defective semiconductor structure 100. Additionally, by forming the HBM component 134 using a die last approach, appropriate thermal analysis may be performed on the semiconductor structure 100 resulting in mitigating thermal challenges during manufacturing.

The RDL 103 provides connections to and from multiple components (e.g., HBM component 134, SoC component 136, and I/O component 132) therefore resulting in increased package density and reduced overall footprint of the semiconductor structure 100. The RDL 103 also provides efficient signal routing and power distribution between the multiple components resulting in improved functional integration. Additionally, the RDL 103 provides efficient heat transfer due to the direct connection between the μ-bumps 130. The direct connect reduces thermal resistance and improves overall thermal management by efficient heat dissipation through the RDL 103. The RDL 103 also provides design flexibility to place components and devices in optimized locations (e.g., high heat producing components next to low heat producing components) to ensure effective heating strategies.

The trapezoid shape of the via 120 provides improved routing capacity between the μ-bumps 130. The trapezoid cross-sectional shape of the via 120 also enhances thermal performance by allowing better heat dissipation between components and therefore reducing overall thermal resistance. The trapezoid cross-sectional shape of the via 120 with a wider top surface than the bottom surface allows for more heat generated from heat generating elements and components (e.g., HBM component 134, SoC component 136, and I/O component 132) mounted to the top surface to transfer through the via 120 down through the RDL 103. Additionally, the trapezoid shape of the via 120 offers improved alignment between components therefore ensuring reliable connections between layers.

Turning to FIG. 2C, an underfill 142 may be formed on top of the RDL 103 and a mold 146 may be subsequently formed surrounding the underfill 142 and on top of the RDL 103. The mold 146 forms a layer on top of the RDL 103 while the underfill 142 is formed in a portion of the mold 146. In some embodiments, the underfill 142 may generally have a rectangular, trapezoidal, triangular, or other cross sectional shape.

The underfill 142 may be formed around each bonded array of μ-bumps 130. The underfill 142 may be formed by injecting an underfill material around the array of μ-bumps 130 and in between the components (e.g., SoC component 136, HBM component 134, and I/O component 132). In some embodiments, the underfill 142 may be formed of epoxy polymer and silica fillers or other combinations of materials. In some embodiments, the underfill 142 may provide thermal expansion matching, mechanical strength, and may fill gaps 144 within the semiconductor structure 100 during the assembly process.

In some embodiments, the underfill 142 may be capillary underfill, no-flow underfill, molded underfill, or wafer-level underfill. Capillary underfill utilizes capillary flow of liquid organic resin binders mixed with inorganic fillers, such as silica, to aid in stiffening the material and reducing the coefficient of thermal expansion. No-flow underfill is applied directly to the semiconductor structure 100 without flowing. No-flow underfill may provide better control over the underfill process and reduce the risk of voids or incomplete coverage. Molded underfill is pre-molded to a specific shape. The molded underfill undergoes a curing process to ensure proper bonding after being placed on the semiconductor device. Wafer-level underfill is applied to the entire semiconductor device before dicing using specialized equipment and processes. Any known underfill material application method may be used, which may be, for example, the capillary underfill method, the molded underfill method, or the printed underfill method.

In one embodiment, a plurality of components (e.g., SoC component 136, HBM component 134, and I/O component 132) may be attached to the dielectric portion 104, within the RDL 103. The underfill 142 may continuously extend underneath the plurality of components and surround the μ-bumps 130. Additionally, the underfill 142 may be formed in a gap 144 between components.

In some embodiments, the underfill 142 may be formed of an epoxy polymer or other appropriate composite material. The underfill 142 may provide mechanical support and structural reinforcement to the semiconductor 100 therefore protecting the μ-bumps 130. In some embodiments, the underfill 142 may also dissipate heat produced by the device 100 due to the large surface area of the underfill 142. The underfill 142 also provides stress relief by providing a compliant layer that reduces mechanical stress in instances in which the components (e.g., HBM component 134, SoC component 136, or I/O component 132) or μ-bumps 130 expand or contract during temperature cycling. The underfill 142 may further prevent moisture ingress by encapsulating the μ-bumps 130 and protecting the connections from moisture and contaminates resulting in long-term reliability. Additionally, the underfill 142 improves the durability of the semiconductor structure 100 by improving the robustness and preventing detachment of the components by providing a protective layer surrounding the components.

The mold 146 may be applied over the top of the RDL 103. In some embodiments, the mold 146 surrounds the underfill 142 material. In some embodiments, the mold 146 is formed of organic resins, such as epoxy resin, fillers, catalysts, and other appropriate materials. The mold 146 is located adjacent to the underfill 142 to form an outside wall. The mold 146 may encapsulate the components and underfill 142 therefore protecting the semiconductor device from external factors such as impact, pressure, moisture, heat, and UV rays. The mold 146 may also maintain the electric insulating properties of the semiconductor device by preventing contact between the components and the environment. For example, the mold 146 may prevent short-circuits due to unwanted interactions. Additionally, the mold 146 may provide the device with proper and easy mounting.

The mold 146 may include an epoxy-containing compound that may be hardened (i.e., cured) to provide a dielectric material portion having sufficient stiffness and mechanical strength. The mold 146 may include epoxy resin, hardener, silica (as a filler material), and other additives. The mold 146 may be provided in a liquid form or in a solid form depending on the viscosity and flowability. Liquid molding compound provides better handling, good flowability, less voids, better fill, and less flow marks. Solid molding compound provides less cure shrinkage, better stand-off, and less die drift. A high filler content (such as 85% in weight) within a molding compound may shorten the time in mold, lower the mold shrinkage, and reduce the mold warpage. Uniform filler size distribution in the molding compound may reduce flow marks, and may enhance flowability. The curing temperature of the molding compound may be in a range from 125° C. to 150° C.

The mold 146 may be cured at a curing temperature to form a matrix that laterally surrounds the underfill 142 and portions of the components (e.g., SoC component 136, HBM component 134, and I/O component 132). the two-dimensional array of semiconductor dies. The molding compound matrix includes a plurality of molding compound die frames that are interconnected to one another. The Young's modulus of pure epoxy is about 3.35 GPa, and Young's modulus of the mold 146 may be higher than Young's modulus of pure epoxy by adding additives. Young's modulus of the mold 146 may be greater than 3.5 GPa. The Young's modulus of the mold 146 may provide sufficient stiffness to mitigate against cracking and stress due to thermal expansion. In some embodiments, suitable alternative molding materials may be used for the mold 146.

The mold 146 may further encapsulate the components to protect the components from damage. For example, the mold 146 may protect the device from mechanical distortion, moisture migration, chemical damage, ultraviolet radiation and heat. In other words, the mold 146 protects components within the device from external damage. Additionally, the mold 146 may dissipate the heat produced by components further providing thermal management.

FIG. 2D illustrates the semiconductor structure 100 undergoing a bonding and debonding process to different carrier wafers 128 and 150. In some embodiments, the first carrier 128 is de-bonded and removed and a second carrier 150 is bonded above the components to the mold 146 using an adhesive 148. In some embodiments, the first carrier 128 and the second carrier 150 are temporarily bonded to the semiconductor structure 100 by an adhesive 148 and may provide mechanical stability during processes, such as thinning, layer deposition, and device integration. In some embodiments, the first carrier 128 and the second carrier 150 may be formed of a ceramic material, metal material, plastic material, aluminum alloy, epoxy glass fabric, glass material, seamless steel, or other appropriate carrier material.

The first carrier wafer 128 may have been bonded to the RDL 103 through an adhesive 126. The first carrier wafer 128 may be an optically transparent material such as glass or sapphire. In this embodiment, the adhesive layer 126 may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer 126 may include a thermally decomposing adhesive material. For example, the adhesive layer 126 may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

In other embodiments, the first adhesive layer 126 may be decomposed by ultraviolet radiation or by a thermal anneal at a debonding temperature. In embodiments in which the carrier wafer 128 includes an optically transparent material and the first adhesive layer 126 includes an LTHC layer, the first adhesive layer 126 may be decomposed by irradiating ultraviolet light through the transparent carrier substrate. The LTHC layer may be absorb the ultraviolet radiation and generate heat, which decomposes the material of the LTHC layer and cause the transparent carrier wafer 128 to be detached from the RDL 103. In embodiments in which the first adhesive layer 126 includes a thermally decomposing adhesive material, a thermal anneal process at a debonding temperature may be performed to detach the carrier wafer 128 from the RDL 103.

FIG. 2E illustrates an example of a further intermediate semiconductor structure 100 having undergone an etching process and a pad formation process and a magnified view of a surface mount pad 158. In some embodiments, the surface mount pads 158 may improve density by allowing more interconnects between components, lower thermal resistance and dissipate heat more efficiently, and lower inductance.

In some embodiments, the dielectric material layers of the RDL 103 may undergo an etch back process to selectively remove portions of the dielectric material 104 and expose a portion of the via 106. The dielectric material 104 may be etched until a height of 1 μm, 2 μm, 5 μm, 7 μm, 8 μm, 10 μm, or 15 μm of a portion of the via 106 is exposed. In some embodiments, the etch back process is a positive etch back process or a plasma etching process. In the positive etch back process, the material is mechanically removed. In the plasma etching process, a plasma etch is applied that carefully removes dielectric portions of the RDL 103 and reveals a portion of the via 106.

Once a portion of the via 106 is revealed, a seed layer may be is deposited by a CVD process, an AVD process, or other appropriate deposition processes. In an embodiment, the seed layer 156 is formed of titanium, titanium-tungsten, or titanium-nitride. Subsequent to depositing the seed layer 156, the pad 152 may be conformally formed below the seed layer 156. In some embodiments, the pad 152 is formed of a conductive material such as copper, silver, tungsten, or other appropriate materials. The pad 152 is formed conformally on the bottom surface and therefore a protrusion 153 may be formed below the via 106. In an embodiment, a plating 154 is formed below the pad 152. The plating 154 may be formed of an alloy such as a tin alloy or other appropriate material.

In some embodiments, the surface mount pads 158 are ball grid arrays (BGAs), quad flat no-leads (QFNs), land grid arrays (LGAs), plastic over-molded BGAs (PBGAs), or other appropriate surface mount pads 158.

In embodiments in which the surface mount pads 158 are BGAs, the BGAs 158 may be used to subsequently mount devices (e.g., connectors and voltage regulator modules) by utilizing interconnected pins along an entire bottom surface of a device. The BGAs 158 provide high density by accommodating multiple pins within a single surface mount pad. Additionally, BGAs 158 provide low thermal resistance due to the overall design. For example, the BGAs 158 directly connect to the RDL 103. The direct contact allows for efficient heat transfer between the BGAs 158 and RDL 103. The direct contact also minimizes the thermal path and as a result reduces the thermal resistance. The BGAs 158 also have a large surface area to allow for heat dissipation. The vias located in the BGAs 158 allow for heat to flow vertically further reducing thermal resistance. The BGAs 158 include a pad that are connected to the metal traces 118 in the RDL 103 and enhance heat dissipation. and enhance performance at high speeds. In addition, the increased and improved strength of the via 106 with pillar 108 may provide additional strength and support to the BGA 158 when compressively applied against connectors 162 and VRM 164 as described below.

In other instances, the surface mount pads 158 are QFNs that have a flat package with exposed metal pads on a bottom surface (not shown). In these embodiments, the QFNs 158 improve thermal performance due to the large, exposed pads that provide a path for heat transfer across the device and decreases thermal resistance. In other words, the large, exposed pads act as a heat sink by carrying the majority of the thermal energy generate and dissipating it to other portions of the device. In yet other instances, the surface mount pads 158 are LGAs that are similar to BGAs, however, the LGAs 158 include an array of landings or pads on a bottom surface instead of solder balls. In yet other instances, the surface mount pads 158 are PBGAs that incorporate a plastic-coated body, a glass-mixture laminated substrate, and etched metallic traces.

In embodiments, the pad 152 may be formed of copper, tungsten, silver, gold, or other appropriate conductive material. The protrusion 154 is an access point to connect to the devices (e.g., connectors 162 and VRMs 164). The protrusion154 may aid in alignment when connecting the devices (e.g., connectors 162 and VRMs 164). Further, the protrusion 154 may encourage the formation of a consistent solder with good electrical and mechanical connections. The protrusion 154 may improve mechanical stability and prevent components from shifting or tilting after connecting. Additionally, the protrusion 154 increases the surface area of the surface mount pads 158 resulting in improved heat transfer between the devices (e.g., connectors 162 and VRMs 164) and the RDL 103.

FIG. 2F illustrates an example of a further intermediate semiconductor structure 100 having undergone a second debonding process, a back-grinding taping process, and a grinding process. In some embodiments, the second carrier 150 is removed and a back-grinding (BG) tape 160 is added to surround the surface mount pads 158.

The second carrier wafer 150 may have been bonded to the mold 146 through an adhesive 148. The second carrier wafer 150 may be an optically transparent material such as glass or sapphire. In this embodiment, the adhesive layer 148 may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer 148 may include a thermally decomposing adhesive material. For example, the adhesive layer 148 may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

In other embodiments, the adhesive layer 148 may be decomposed by ultraviolet radiation or by a thermal anneal at a debonding temperature. In embodiments in which the carrier wafer 150 includes an optically transparent material and the adhesive layer 148 includes an LTHC layer, the adhesive layer 148 may be decomposed by irradiating ultraviolet light through the transparent carrier substrate. The LTHC layer may be absorb the ultraviolet radiation and generate heat, which decomposes the material of the LTHC layer and cause the transparent carrier wafer 150 to be detached from the mold 146. In embodiments in which the adhesive layer 148 includes a thermally decomposing adhesive material, a thermal anneal process at a debonding temperature may be performed to detach the carrier wafer 150 from the mold 146.

In some embodiments, the BG tape 160 may be a UV curable tape, a non-UV tape, or other appropriate BG tapes. The UV curable tape may undergo a UV curing reaction in response to being exposed to UV irradiation. The UV curable tape may undergo a polymerization reaction under UV irradiation which hardens the UV curable tape and causes the UV curable tape to lose adhesive strength resulting in an easier peel. In contrast, non-UV tape may provide reliable protection without the UV curing process.

In some embodiments, the BG tape 160 is applied onto the surface that has the surface mount pads 158 formed thereon. Once the BG tape 160 is applied on the surface, a grinding process removes portions of the mold 146 exposing the components (e.g., SoC component 136, HBM component 134, and I/O component 132). After grinding, the BG tape 160 is removed. The BG tape 160 may protect the surface mount pads 158 during the grinding and/or thinning process. For example, the BG tape 160 may prevent wafer surface contamination caused by infiltration of grinding fluid or other debris.

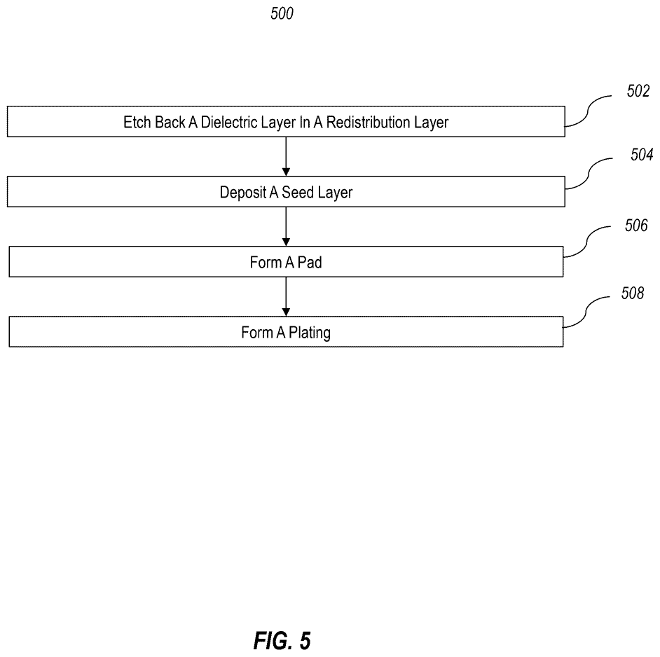

Optionally, the semiconductor structure 100 may also undergo other processing and cleaning processes such as sawing and laser drilling. With reference to FIG. 5G, in an embodiment, the processing includes mold sawing and laser drilling the sides of the semiconductor structure 100. Additionally, post sawing and drilling, the semiconductor structure 100 undergoes a laser drilling cleaning process. The sawing, laser drilling, and laser drilling cleaning processes are used to remove portions of the mold layer 146 and RDL 103 to match with the form factor of the semiconductor structure 100. The form factor defines dimensions of the desired final semiconductor structure 100.

FIG. 2H illustrates an example of the semiconductor structure 100 with connected devices. As shown, the BG tape 160 may be removed and devices, such as connectors 162 and VRMs 164, may be connected to the surface mount pads 158.

The connectors 162 may provide the semiconductor structure 100 to connect and communicate with other devices. In some embodiments, the connectors 162 may be board-to-board connectors, orthogonal connectors, PCB connectors, circular connectors, D-sub connectors, fiber optic connectors, USB connectors, or other appropriate connectors. Other connectors are within the contemplated scope of disclosure. As shown, the semiconductor structure 100 includes two connectors 162. Fewer or more connectors 162 may be used in the semiconductor structure 100. In some embodiments, the connectors may be the same type or different types of connectors. In some embodiments, the connectors 162 may include ingress protection to protect again dust, water, or other environmental factors.

In some embodiments, the semiconductor structure 100 includes one or more VRMs 164. As shown, the semiconductor structure 100 includes two VRMs 164. In alternative embodiments, the semiconductor structure 100 may include a single VRM, two VRMs, three VRMs, or more than three VRMs. The VRMs 164 may regulate the voltage from the power source to the integrated components. In some embodiments, the VRMs 164 may act as a switching regulator using a buck converter for efficiency.

The RDL 103 provides connections to and from multiple devices (e.g., connectors 162 and VRMs 164) therefore resulting in increased package density and reduced overall footprint of the semiconductor structure 100. The RDL 103 also provides efficient signal routing and power distribution between the multiple devices resulting in improved functional integration. Additionally, the RDL 103 provides efficient heat transfer due to the direct connection between the surface mount pads 158. The direct connect reduces thermal resistance and improves overall thermal management by efficient heat dissipation through the RDL 103. The RDL 103 also provides design flexibility to place devices in optimized locations (e.g., high heat producing devices next to low heat producing components) to ensure effective heating strategies.

The trapezoid shape of the via 106 provides improved routing capacity between the devices (e.g., connectors 162 and VRMs 164). The trapezoid cross-sectional shape of the via 106 also enhances thermal performance by allowing better heat dissipation between devices and therefore reducing overall thermal resistance. The trapezoid cross-sectional shape of the via 106 with a wider top surface than the bottom surface allows for more heat generated from heat generating elements and devices mounted to the surface mount pads 158 to transfer through the via 106 towards the RDL 103. Additionally, the trapezoid shape of the via 106 offers improved alignment between the RDL 103 and surface mount pads 158 therefore ensuring reliable connections between layers.

FIG. 2I illustrates an example of the semiconductor structure 100 with an attached thermal module 166. In some embodiments, the thermal module 166 may provide a mechanism for removing heat in the semiconductor structure 100. The thermal module 166, in some embodiments, may be a heat pipe thermal module or other appropriate thermal modules for cooling the semiconductor structure 100. In some embodiments, the thermal module 166 may comprise a cold plate positioned on top of the components. The cold plate may include, for example, a cold plate base (e.g., a copper plate) and a cold plate cover on the cold plate base. The thermal module 166 may further comprise, for example, one or more heat pipes on the cold plate base.

In some embodiments, the thermal module 166 may include a remote type heat-pipe heat sink and be part of a remote-type heat-pipe heat sink design. In some embodiments, the heat generated from the HBM 134 or other components may be dissipated through the cold plate base. The heat pipes attached to the cold plate base may transfer the heat removed from the HBM 134 or other components to the heat sink.

In some embodiments, the cold plate base may include a protruding portion (e.g., protrusion, pedestal base, etc.) on the interposer module (e.g., a chip on wafer (CoW) die) for cooling. In some embodiments, the thermal module 166 may be used, for example, on a high-performance computing (HPC) fan-out package. The thermal module 166 may include a cavity design in the protruding portion of the cold plate base with one or more of the heat pipes may be bent with U-shape and soldered in the cavity. In some embodiments, the thermal module 166 may help to improve a thermal performance for the semiconductor package (e.g., ring-type semiconductor package).

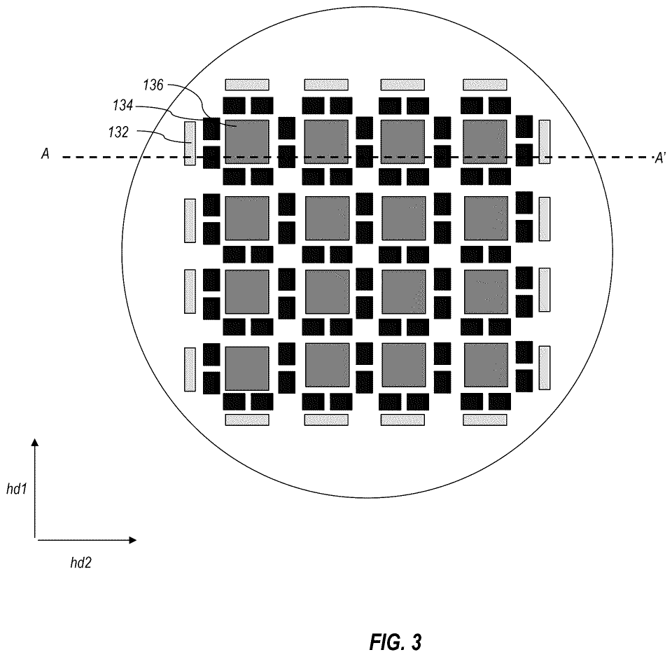

Referring now to FIG. 3 that illustrates a top view of the semiconductor structure 100. The cut line AA′ illustrates the location of the cross-section view shown in FIGS. 1A-1C and 2A-2H. As shown, the semiconductor structure 100 includes multiple SoC components 136 in a two-dimensional (2D) array in which each SoC component 136 is surrounded by eight (8) HBM components 134. Additionally, as shown, I/O components 132, form an outside perimeter in which each I/O component 132 is adjacent to two HBM components 134.

As shown in FIG. 3, the configuration with an outer perimeter of I/O components 132 adjacent to HBM components 134 that surround SoC components 136 allows for HBM components 134 to be incorporated while mitigating thermal concern. More specifically, by separating the HBM components 134, the RDL 103, the underfill 142, the mold 146, and the μ-bumps 130 may effectively dissipate the heat produced by the HBM components 134. One skilled in the art will appreciate that various configurations are possible with a variety of components, including but not limited to the incorporation of HBM components.

The following discussion now refers to a number of methods and method steps. Although the method steps are discussed in specific orders or are illustrated in a flow chart as occurring in a particular order, no order is required unless expressly stated or required because an act is dependent on another act being completed prior to the act being performed.

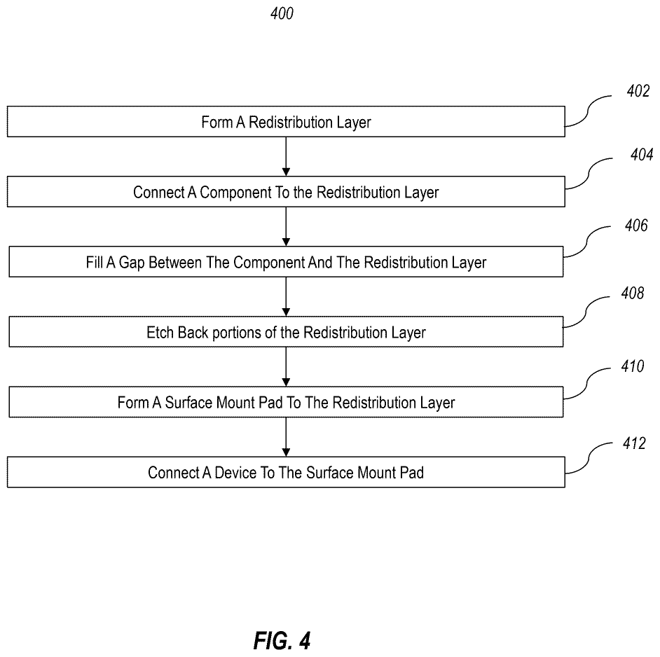

Embodiments are now described in connection with FIG. 4, which illustrates a flow diagram of example method 400 for forming a semiconductor structure 100, according to an embodiment of the present disclosure. In some embodiments, step 402 comprises forming a redistribution layer 103, wherein the redistribution layer 103 includes a plurality of connecting vias 120 and at least one surface mount pad via 106, wherein a top surface width of each via 106/120 is larger than a bottom surface width of each via 106/102. Referring to FIGS. 1A-1C, in step 402 of method 400, a redistribution layer 103 is formed. The redistribution layer 103 includes metal traces 118, surface mount pad vias 106, connecting vias 120, and a dielectric layer 104.

In some embodiments, a first layer of the RDL 103 is formed by etching a cavity in a dielectric material layer 104. Step 402 optionally includes forming a conductive pillar 108 in the surface mount pad via 106, forming a seed layer 110 surrounding the conductive pillar 108 and the surface mount pad via 106, and filling the surface mount pad via 106 with a conductive material. Additionally, step 402 may include forming a metal trace 118 above the surface mount pad via 106.

In some embodiments, step 402 includes forming at least six layers in the RDL 103 wherein each layer includes at least a metal trace 118 or a via (e.g., surface mount pad via 106 or connecting via 120). Step 402 may further include forming a metal trace 118 below the connecting vias 120 and forming a metal trace 118 above the connecting vias 118. Optionally, step 402 includes forming a seed layer 124 around the connecting vias 120.

In some embodiments, step 404 comprises connecting a component (e.g., I/O component 132, HBM component 134, or SoC component 136) to the redistribution layer 103 by a plurality of μ-bumps 130, wherein each μ-bump 130 is connected to the top surface width of a connecting via 120. The wider top surface of the connecting via 120 improves the alignment of the μ-bump 130 and may promote improved thermal mitigation by allowing more thermal energy to flow vertically away from the heat generating components. Referring to FIG. 2B, in step 404 of method 400, the components may include a HBM component 134, SoC component 136, or an I/O component 132. In some embodiments, the SoC components 136 may be placed in a two-dimensional array in a first horizontal direction hd1 and a second horizontal direction hd2. The SoC components 136 may be placed on the RDL 103 so as to be surrounded on all sides in a top view by HBM components 134. In addition, I/O components 132 may be placed on the RDL 103 and connected by μ-bumps 130 such that the I/O components 132 surround the two-dimensional array of SoC components 136 and HBM components 134 in a top view. In other words, the SoC components 136 and HBM components 134 may be placed such that the I/O components 132 surround an outside perimeter of the semiconductor structure 100, as shown in FIG. 3. In some embodiments, the components are connected to the redistribution layer 103 by a μ-bump 130. In some embodiments, the μ-bumps 130 may have a pitch of at least 150 μm. Additionally, in some embodiments, the μ-bumps 130 may have a critical dimension of at least 80 μm. In some embodiments, the μ-bumps 130 may be formed of a solder material.

In some embodiments, step 406 comprises filling a gap 144 between the component (e.g., I/O component 132, HBM component 134, or SoC component 136) and the redistribution layer 103 with a mold 146 and an underfill 142, wherein the mold 146 forms an outer edge and the underfill 142 is located between the components (e.g., I/O component 132, HBM component 134, or SoC component 136) and the redistribution layer 103. Referring to FIG. 2C, in step 406 of method 400, the mold 146 and the underfill 142 form a layer above the RDL 103. In some embodiments, the mold 146 forms a sidewall of the semiconductor structure 100. The underfill 142 may surround the μ-bumps 130 and a portion of the components while the mold 146 may surround the underfill 142.

In some embodiments, step 408 comprises etching back the redistribution layer 103 to expose at least a portion of the surface mount pad via 106 and step 410 comprises forming a surface mount pad 158 on the surface mount pad via 106, wherein the surface mount pad 158 is connected to the bottom surface width of the surface mount pad via 106 and the surface mount pad 158 includes a protrusion 154. Referring to FIG. 2E, in step 408 of method 400, a portion of the RDL 103 may etched back to expose at least a portion of the surface mount pad via 106. In some embodiments, step 408 includes depositing a seed layer 156 in contact with the dielectric layer 104 and the via 106. A pad 152 is formed in contact with the etched portion formed of a conductive material such as copper, tungsten, silver, gold, or other appropriate method. Because the pad 152 is formed conformally, a protrusion 153 is also formed below the via 106. In embodiments, a plating 154 may be formed below the pad 152. In some embodiments, the plating 154 may be formed of an alloy such as a tin alloy.

In some embodiments, step 412 comprises connecting a device (e.g., connectors 162 or VRMs 164) to a bottom surface of the surface mount pad 158. Referring to FIG. 2G, in step 412 of method 400, the devices may be hybrid bonded to the surface mount pads 158. In some embodiments, method 400 may further comprise attaching a thermal module 166 above the components. In some embodiments, the thermal module 166 may dissipate heat from the components, such as the HBM 134, and mediates thermal concerns.

Embodiments are now described with reference to FIG. 5, which illustrates a flow diagram of example method 500 for forming a surface mount pad 158, according to an embodiment of the present disclosure. In some embodiments, step 502 comprises etching back at least a portion of a dielectric layer 104 in a redistribution layer 103.

FIG. 2E, in step 408 of method 400, at least a portion of the RDL 103 is etched back to expose at least a portion of the via 106. In an embodiment, etching back the portion of the dielectric layer 104 removes at most 10 μm of a height of the dielectric layer 104.

In some embodiments, step 504 includes depositing a seed layer 156 on a bottom surface of the redistribution layer 103 and over an exposed portion of the surface mount pad via 106. The seed layer 156 may be deposited using CVD, AVD, or other appropriate deposition methods. The seed layer 156 may be formed of titanium, titanium tungsten, titanium nitride, or other appropriate material.

In some embodiments, step 506 includes forming a pad 152 below the bottom surface, wherein the pad 152 includes a protrusion 153 and step 508 includes forming a plating 154 below the pad 152. In embodiments, the pad 152 is formed conformally beneath the etched RDL 103 and therefore includes a protrusion 153 below the via 106. The pad 152 may be formed of a conductive material such as copper, tungsten, silver, gold, or other appropriate material. The plating 154 may be formed of an alloy such as tin alloy.

Referring to all drawings and according to various embodiments of the present disclosure, a method of forming a semiconductor structure 100 includes forming a RDL 103, wherein the RDL 103 includes a plurality of vias (120, 106), wherein the plurality of vias include connecting vias 120 and at least one surface mount pad via 106, wherein a top surface width of each via 106, 120 is larger than a bottom surface width of each via 106, 120; etching back the RDL 103 to expose at least a portion of the at least one surface mount pad via 106; and attaching a surface mount pad 158 to the surface mount pad via 106, wherein the surface mount pad 158 is connected to the bottom surface of the surface mount pad via 106 and the surface mount pad includes a protrusion 153.

In some embodiments, forming the RDL 103 further includes: etching a in a dielectric material layer to form a surface mount pad cavity; forming a pillar 108 formed of a conductive material in the surface mount pad cavity; depositing a seed layer 110 surrounding the pillar 108 and a surface of the surface mount pad cavity; and forming the conductive material in the surface mount pad cavity to form the surface mount pad via 106 with a conductive material. In some embodiments, forming the RDL 103 further includes forming a metal trace 118 above the surface mount pad via 106. In some embodiments, forming the RDL 103 further includes etching in a dielectric material layer to form a connecting via cavity; depositing a seed layer 124 on a surface of the connecting via cavity; and forming a conductive material in the connecting via cavity to form the connecting via 120. In some embodiments, forming the RDL 103 further includes forming a metal trace 118 above the connecting via 120. In some embodiments, the method further includes attaching a thermal module 166 above the plurality of components (e.g., I/O component 132, HBM component 134, or SoC component 136). In some embodiments, forming the RDL 103 further includes forming at least six layers, wherein each layer includes at least a metal trace 118 or a via 106, 120. In some embodiments, etching back the dielectric layer 104 exposes a portion of a surface mount pad via 106, wherein the surface mount pad via 106 has a top surface width that is larger than a bottom surface width. In some embodiments, the method further includes depositing a surface mount pad seed layer 156 partially in contact with a surface mount pad via seed layer 124. In some embodiments, etching back the dielectric layer 104 removes at most 10μm of a height of the dielectric layer.

In another embodiment, a method of forming a pillar within a via includes etching a dielectric material layer 103 to form a cavity; forming a pillar 108 formed of a conductive material in the cavity; and forming a conductive material in the cavity to form a via 106.

In some embodiments, the method further includes depositing a seed layer surrounding the pillar 110 and a surface of the cavity 124.

In another embodiment, a semiconductor structure 100 includes a surface mount pad 158, wherein the surface mount pad 158 includes a pad 152 and a plating 154, wherein the pad 152 is in contact with the bottom width of the via 106 and has a protrusion 153, and a seed layer 156 located above the surface mount pad 152 and partially in contact with a via seed layer 124.

In some embodiments, the semiconductor structure 100 further includes a RDL 103 comprising a via 106 and a metal trace 118 located within a dielectric layer 104, wherein the via 106 is formed below the metal trace 118, a top surface width of the via 106 is larger than a bottom surface width of the via 106, a pillar 108 located in the via 106 surrounded by a seed layer 110, and the via 106 is filled with a conductive material. In some embodiments, the RDL 103 further includes a connecting via 120, wherein the connecting via 120 has a top surface width that is larger than a bottom surface width. In some embodiments, a plurality of μ-bumps 130, wherein each μ-bump connects a component of the plurality of components (e.g., I/O component 132, HBM component 134, or SoC component 136) to a connecting via 120 in the RDL 103 and the μ-bumps 130 have a pitch of at most 150μm. In some embodiments, the conductive material is copper. In some embodiments, the pad 152 is formed of copper and the plating 154 is formed of a tin alloy. In some embodiments, wherein the dielectric material 104 includes a plurality of dielectric layers and each dielectric layer includes at least one connecting via 120, at least one surface mount pad via 106, or at least one metal trace 118. In some embodiments, the semiconductor structure 100 further includes a plurality of components (e.g., I/O component 132, HBM component 134, or SoC component 136) including at least one high-bandwidth memory component 134; a plurality of μ-bumps 130, wherein each μ-bump 130 connects a component (e.g., I/O component 132, HBM component 134, or SoC component 136) to a connecting via 120 in the RDL 103 and the μ-bumps 130 have a pitch of at most 150 μm; an underfill layer 142, wherein the underfill layer 142 is located between the components (e.g., I/O component 132, HBM component 134, or SoC component 136) and the RDL 103 and surrounds the μ-bumps 130; a mold layer 146, wherein the mold layer 146 surrounds each side and a top of the underfill layer 142 and forms a sidewall; at least one device (e.g., connectors 162 or VRMs 164), wherein the device (e.g., connectors 162 or VRMs 164) is attached to a bottom surface of the surface mount pad 158; and a thermal module 166 located above the components (e.g., I/O component 132, HBM component 134, or SoC component 136).

The various embodiments disclosed herein may provide various advantages and improvements. For example, various embodiments may provide for proper integration between a variety of components within a semiconductor device, such as a wafer-scale heterogenous integration device or a CoW-R SoW device. As a result, disclosed embodiments may improve complex applications, such as HPC applications, while addressing thermal challenges. Various embodiments disclosed herein may utilize a HBM die last approach when forming the semiconductor device. As a result, disclosed embodiments increase yield while preventing yield loss due to HBM and SoC issues. Additionally, various embodiments disclose herein the HBM die last approach in combination with an organic interposer may prevent thermal concerns. Overall, various disclosed embodiments may provide thermal regulation and reduce yield loss in semiconductor devices with HBM components while maintaining HPC application capabilities.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a redistribution layer, wherein the redistribution layer includes a plurality of vias, wherein the plurality of vias comprise connecting vias and at least one surface mount pad via, wherein a top surface width of each via of the plurality of vias is larger than a bottom surface width of each via of the plurality of vias;
etching back the redistribution layer to expose at least a portion of the at least one surface mount pad via;
attaching a surface mount pad to each of the at least one surface mount pad via, wherein the surface mount pad is connected to a bottom surface of the surface mount pad via and the surface mount pad includes a protrusion.

2. The method of claim 1, wherein forming the redistribution layer further comprises:
etching a dielectric material layer to form a surface mount pad cavity;
forming a pillar formed of a conductive material in the surface mount pad cavity;
depositing a seed layer surrounding the pillar and a surface of the surface mount pad cavity; and
forming the conductive material in the surface mount pad cavity to form the surface mount pad via.

3. The method of claim 2, wherein forming the redistribution layer further comprises forming a metal trace above the surface mount pad via.

4. The method of claim 1, wherein forming the redistribution layer further comprises:
etching in a dielectric material layer to form a connecting via cavity;
depositing a seed layer on a surface of the connecting via cavity; and
forming a conductive material in the connecting via cavity to form the connecting via.

5. The method of claim 4, wherein forming the redistribution layer further comprises forming a metal trace above the connecting via.

6. The method of claim 1, further comprising attaching a thermal module above the plurality of components.

7. The method of claim 1, wherein forming the redistribution layer comprises forming at least six layers, wherein each layer includes at least one of a metal trace or a via.

8. The method of claim 1, wherein etching back the dielectric layer exposes a portion of a surface mount pad via, wherein the surface mount pad via has a top surface width that is larger than a bottom surface width.

9. The method of claim 1, further comprising depositing a surface mount pad seed layer partially in contact with a surface mount pad via seed layer.

10. The method of claim 1, wherein etching back the dielectric layer removes at most 10 μm of a height of the dielectric layer.

11. A method of forming a pillar within a via comprising:
etching a dielectric material layer to form a cavity;
forming a pillar formed of a conductive material in the cavity; and
forming a conductive material in the cavity to form a via.

12. The method of claim 11, further comprising depositing a seed layer surrounding the pillar and a surface of the cavity.

13. A semiconductor structure, comprising:
a surface mount pad, wherein the surface mount pad includes a pad and a plating, wherein the pad is in contact with the bottom width of the via and has a protrusion; and
a seed layer located above the surface mount pad and partially in contact with a via seed layer.

14. The semiconductor structure of claim 13, further comprising a redistribution layer comprising a via and a metal trace located within a dielectric material, wherein the via is formed below the metal trace, a top surface width of the via is larger than a bottom surface width of the via, a pillar located in the via surrounded by a pillar seed layer, and the via is lined with the via seed layer and filled with a conductive material.

15. The semiconductor structure of claim 14, wherein the redistribution layer further comprises a connecting via, wherein the connecting via has a top surface width that is larger than a bottom surface width.

16. The semiconductor structure of claim 14, further comprising a plurality of μ-bumps, wherein each μ-bump connects a component of the plurality of components to a connecting via in the redistribution layer and the μ-bumps have a pitch of at most 150 μm.

17. The semiconductor structure of claim 16, further comprising:
an underfill layer, wherein the underfill layer is located between the plurality of components and the redistribution layer and surrounds the μ-bumps; and
a mold layer, wherein the mold layer surrounds each side and a top of the underfill layer and forms a sidewall.

18. The semiconductor structure of claim 13, wherein the pad is formed of copper and the plating is formed of a tin alloy.

19. The semiconductor structure of claim 13, wherein the dielectric material includes a plurality of dielectric layers and each dielectric layer includes at least one connecting via, at least one surface mount pad via, or at least one metal trace.

20. The semiconductor structure of claim 13, further comprising:
a plurality of components including at least one high-bandwidth memory component;
at least one device, wherein the device is attached to a bottom surface of the surface mount pad; and
a thermal module located above the plurality of components.
